(19) United States
(12) Patent Application Publication
(10) Pub. No.: US 2025/0218873 A1
(43) Pub. Date: Jul. 3, 2025

(54) PROCESSING AND DETECTING APPARATUS

(71) Applicant: PlayNitride Display Co., Ltd., MiaoLi County (TW)

(72) Inventor: Yen-Mu Chen, MiaoLi County (TW)

(73) Assignee: PlayNitride Display Co., Ltd., MiaoLi County (TW)

(21) Appl. No.: 18/396,701

(22) Filed: Dec. 27, 2023

(51) Int. Cl. H01L 21/66; G01N 21/31; G02B 26/10

(52) U.S. Cl. CPC H01L 22/12; G01N 21/3151; G02B 26/101

(57) ABSTRACT

A processing and detecting apparatus includes a stage, a processing unit, a processing scanner and at least one detection scanner. The stage is configured to place a sample to be processed. A surface of the sample to be processed has a plurality of processing positions. The processing unit is disposed relative to the stage to process the sample to be processed. The processing scanner is configured to scan the sample to be processed. The processing scanner controls the processing unit to process the processing positions sequentially at a scanning frequency. The detection scanner includes an information capturing unit and a scanning output unit. The information capturing unit synchronously receives a piece of detection information for each processing position through the processing scanner, the scanning output unit is signally connected to the information capturing unit, and outputs each piece of detection information at the scanning frequency.

### BACKGROUND

### Technical Field

The invention is related to a processing and detecting apparatus.

### Description of Related Art

Currently, pulse lasers combined with galvo scanners can achieve rapid and massive transfer of micro-light-emitting diodes (micro-LEDs), with an efficiency of up to tens of thousands per second.

Due to the brightness and resolution requirements of micro light-emitting diode detection, the charge-coupled device (CCD) exposure frame rate can only be limited to less than dozens of frames per second, which is far less than the speed of the transfer process. Therefore, the mainstream practice in the production line is to handle the transfer process and inspection in separate stations.

The general inspection method is to quickly move the wafer on a three-dimensional platform to allow the charge-coupled device to capture different positions frame by frame. However, micron-level quick stops are difficult to control, and there are also problems with alignment accuracy, resulting in slower efficiency.

In recent years, a way to improve efficiency has been proposed to use a galvanometer with a prism to generate a plurality of detection light spots. The field of view (FOV) of each light spot covers a plurality of chips, and then the chips are imaged to different positions of the charge-coupled device. That is, a galvanometer is used to scan the detection light spot on different positions of the wafer to replace the three-dimensional movement of the platform.

However, the above method uses a galvanometer to overcome the problem of platform movement, but the detection light spot is used to shoot a plurality of chips at one time, which is different from the light spot of the laser process. Therefore, it is still multiple-station type and cannot be synchronized with the transfer process.

### SUMMARY

The invention provides a processing and detecting apparatus that can perform simultaneous detection when processing a sample to be processed, thereby replacing the existing multiple-station process and improving production efficiency.

An embodiment of the invention provides a processing and detecting apparatus, including a stage, a processing unit, a processing scanner and at least one detection scanner. The stage is configured to place a sample to be processed. A surface of the sample to be processed has a plurality of processing positions. The processing unit is disposed relative to the stage to process the sample to be processed. The processing scanner is configured to scan the sample to be processed. The processing scanner controls the processing unit to process the processing positions sequentially at a scanning frequency. At least one detection scanner includes an information capturing unit and a scanning output unit. The information capturing unit synchronously receives a piece of detection information for each processing position through the processing scanner, the scanning output unit is signally connected to the information capturing unit, and outputs each piece of detection information at the scanning frequency.

Based on the above, in the processing and detecting apparatus according to the embodiment of the invention, the surface of the sample to be processed has a plurality of processing positions, and the processing scanner controls the processing unit with a scanning frequency to process the plurality of processing positions sequentially, the information capturing unit synchronously receives a piece of detection information for each of the plurality of processing positions via the processing scanner, and the scanning output unit is connected to the information capturing unit and outputs each piece of detection information at a scanning frequency. Therefore, when processing the sample to be processed, detection can be performed simultaneously. For example, in the process of mass transfer, massive detection can be carried out simultaneously, replacing the existing multiple station process and improving production efficiency.

### BRIEF DESCRIPTION OF THE DRAWINGS

FIG. 1 is a schematic diagram of a light path of a processing and detecting apparatus according to an embodiment of the invention.

FIG. 2A is a schematic front view of the pixel array and imaging area of the receiving unit of the processing and detecting apparatus in FIG. 1.

FIG. 2B is a partially enlarged schematic diagram of the imaging area according to FIG. 2A and the image formed thereon.

FIG. 3 is a schematic diagram of the light path of a processing and detecting apparatus according to another embodiment of the invention.

FIG. 4 is a schematic diagram of the light path of a processing and detecting apparatus according to another embodiment of the invention.

### DESCRIPTION OF THE EMBODIMENTS

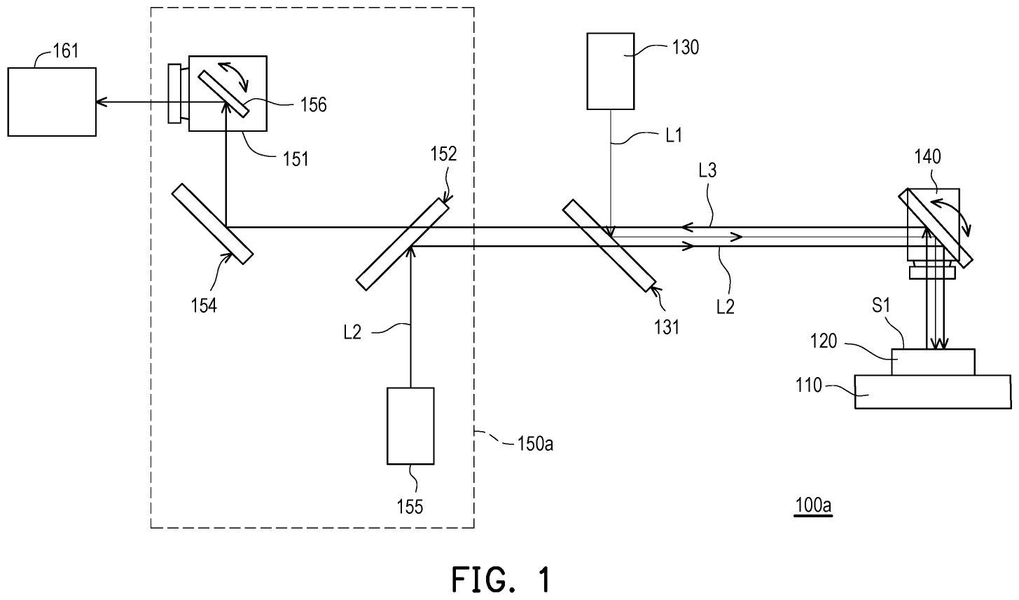

FIG. 1 is a schematic diagram of a light path of a processing and detecting apparatus according to an embodiment of the invention. Please refer to FIG. 1. The processing and detecting apparatus 100a of this embodiment includes a stage 110, a processing unit 130, a processing scanner 140 and a detection scanner 150a. The stage 110 is configured to place a sample 120 to be processed, and the surface S1 of the sample 120 to be processed has a plurality of processing positions. The processing unit 130 is disposed relative to the stage 110 to process the sample 120 to be processed. The processing scanner 140 is configured to scan the sample 120 to be processed, and controls the processing unit 120 to process the plurality of processing positions in sequence with a scanning frequency. In this embodiment, the processing unit 130 may be a laser light source, such as a pulse laser light source. The processing unit 130 provides the processing laser L1, and the position where the processing laser L1 is projected onto the sample 120 to be processed is controlled by the processing scanner 140.

The detection scanner 150a includes an information capturing unit 151 and a scanning output unit 156. The information capturing unit 151 receives a piece of detection information L3 of each processing position synchronously (synchronization may mean at the same time or not at the same time, but after a specific moment of processing time) via the processing scanner 140. The scanning output unit 156 is signally connected to the information capturing unit 151, and outputs each piece of detection information L3 at the scanning frequency. In this embodiment, the detection information L3 is the laser light source reflected from surface S1 of the sample 120 to be processed.

In this embodiment, the detection scanner 150a may further include a beam splitter 152 and a reflector 154, and the scanning output unit 156 may be a scanning galvanometer. The beam splitter 152, the reflector 154 and the scanning output unit 156 are respectively located on the light path from the processing scanner 140, that is, on the transmission path of the detection information L3.

The laser light spot of the processing unit 130 processes the sample 120 to be processed (when the sample 120 to be processed is a wafer, for example, each chip in the wafer is processed), the reflected detection information L3 is scanned by the processing scanner 140.

In this embodiment, the detection scanner 150a also includes a light source module 155, which is configured to provide detection light L2. In this embodiment, the detection light L2 may be the detection light L2 of a single wavelength. In another embodiment, the detection light L2 is, for example, the detection light L2 mixed with a plurality of lights of different wavelengths. Additionally, the light source module 155 may be a continuous light source or a pulse light source. In this embodiment, the beam splitter 152 can reflect the detection light L2 to the processing scanner 140, and can allow the detection information L3 to pass through and be transmitted to the reflector 154. In another embodiment, a polarizing beam splitter (PBS) plus a quarter wave plate can be used to replace the beam splitter 152. The reflector 154 then reflects the detection information L3 to the information capturing unit 151. For example, the information capturing unit 151 includes a lens that can project the detection information L3 onto the scanning output unit 156, or includes a light incident surface that allows the detection information L3 to pass through and be transmitted to the scanning output unit 156, the light incident surface is, for example, a light incident surface of the information capturing unit 151, which allows the detection information L3 to penetrate through.

The light source module 155 is connected (for example, coupled by the light path) to the processing scanner 140 and the information capturing unit 151. The light source module 155 has a light path, and the light path is controlled by the processing scanner 140 so that the light path is coaxial with a vector of each of the processing positions of the sample 120 to be processed. Each piece of detection information is the light signal reflected from the surface S1 of the sample 120 to be processed.

The dichroic mirror 131 is set on the light path of the detection light L2 and the processing laser L1, and can be configured to reflect the processing laser L1, while allowing the detection light L2 to pass through and be transmitted to the sample 120 to be processed, and allowing the returned detection information L3 to pass through and be transmitted to the information capturing unit 151. The processing laser L1 being incident on the surface S1 of the sample 120 to be processed by the processing unit 130 and the detection information L3 reflected from the sample 120 to be processed are controlled by the processing scanner 140 at each of the processing positions and movement therebetween. Therefore, the processing laser L1 and detection information L3 are always coaxial. In an embodiment, the detection light L2 can also be coaxial with the processing laser L1 through the processing scanner 140.

In this embodiment, the processing and detecting apparatus 100a also includes a receiving unit 161, which is connected (for example, coupled by a light path) to the scanning output unit 156 of the detection scanner 150a to receive detection information L3. The location of the signal source received by the detection scanner 150a is determined by the processing scanner 140.

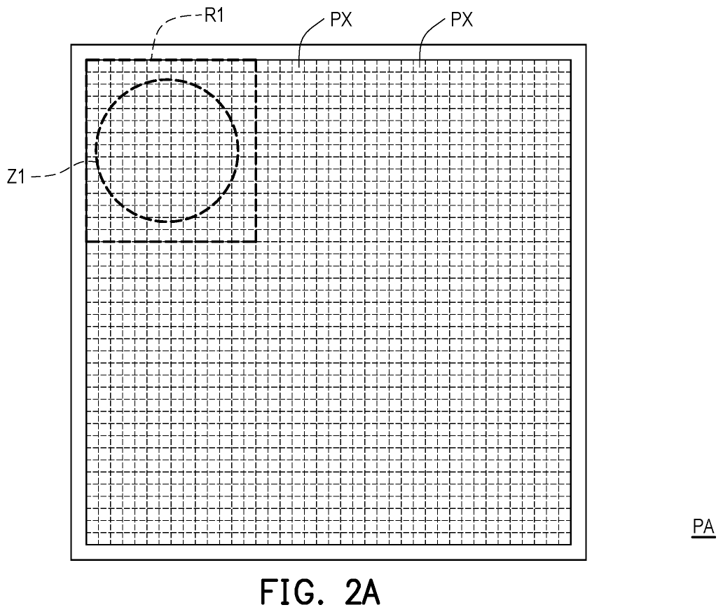

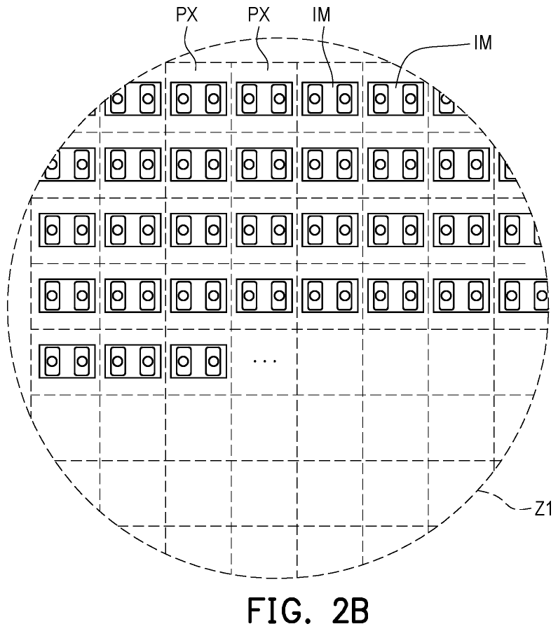

FIG. 2A is a schematic front view of the pixel array and imaging area of the receiving unit of the processing and detecting apparatus in FIG. 1. FIG. 2B is a partially enlarged schematic diagram of the imaging area according to FIG. 2A and the image formed thereon. Please refer to FIG. 2A and FIG. 2B. In this embodiment, the receiving unit 161 is an image sensor, and the pixel array PA of the image sensor has a plurality of pixels PX arranged in an array. The receiving unit 161 has a plurality of imaging areas R1. Each imaging area R1 covers a plurality of pixels PX. Each piece of detection information includes the image IM of one of the processing positions, and each piece of detection information is respectively imaged through the scanning output unit 156 on a plurality of different imaging areas R1 (an image area R1 is, for example, one of the imaging areas R1 shown in FIG. 2A, and a plurality of different imaging areas R1 can be arranged in an array and cover different pixels PX of the pixel array PA respectively).

In this embodiment, when the processing laser L1 of the processing unit 130 and the detection information L3 of the detection scanner 150a are coaxial, the surface S1, of each sample 120 to be processed, which is processed by the processing laser L1 is imaged onto the receiving unit 161. When the processing scanner 140 quickly scans the surface S1 processed by the processing laser L1, the scanning output unit 156 (i.e., the scanning galvanometer which includes a scanning mirror) of the detection scanner 150a also scans quickly, and the position image of the detection information L3 in the imaging space of the receiving unit 161 is respectively projected on different positions of the receiving unit 161. In an embodiment, the sample 120 to be processed is, for example, a micro-light-emitting diode array, and the lens of the receiving unit 161 or other lens is used with the scanning output unit 156 to form the image IM on the pixel PX, and the image IM is, for example, an image of a micro-light-emitting diode (micro-LED chip).

As shown in FIG. 2B, taking the receiving unit 161 being an image sensor as an example, the detection information L3 received by the receiving unit 161 is the image IM of the micro-light-emitting diode chip at each processing position (for example, the image IM shown in the local area Z1 in the imaging area R1). Since the required detection information L3 is the state of the micro-light-emitting diode chip after the laser processing process, the light source module 155 can provide an additional illumination source.

Herein, if each chip requires 50×50 pixels to resolve the image, when the resolution of the receiving unit 161 is 2000×2000, each frame of the receiving unit 161 can accommodate 40×40=1600 chip images.

That is, each micro-LED chip shown in FIG. 2B occupies 50×50 pixels, and each frame of the receiving unit 161 can capture the processed images of 1,600 micro-LED chips. In each frame of the receiving unit 161, the processing scanner 140 and the scanning output unit 156 scan synchronously. While the processing scanner 140 scans the sample 120 to be processed (such as a wafer), the scanning output unit 156 (i.e. the scanning galvanometer) scans the processed images of 1600 chips onto 1600 positions of the receiving unit 161, forming in-situ and on-target fast analysis technology.

For a wafer with 16 million wafers, the conventional technology uses a high-speed platform movement inspection method, which takes about 20 minutes for each wafer. Using the synchronized scanning method of the above-mentioned processing and detecting processes, taking the current common hardware conditions as an example, commercially available charge-coupled devices only need an exposure speed of 30 frames/second (frame/sec), it can capture 48,000 chip images per second, so the receiving unit 161 only needs 333 seconds to complete the storage of detection information, and the efficiency can be improved by up to 3 to 4 times. In addition, compared with the existing technology that only uses galvanometers to detect a plurality of processed images at the same time, this embodiment synchronously performs processing and detecting scanning on the sample 120 to be processed, and enables massive transfer and massive detection to be completed simultaneously in one station, eliminating the need for loading time/unloading time due to the transfer process and the detection process being at different stations.

In an embodiment, the scanning movement period for the processing scanner 140 to complete one processing and move the light spot to the next processing position is, for example, within a few microseconds, which is determined by the writing speed limit of the detection scanner 150a and the receiving unit 161.

In another embodiment, for indirect image detection requirements, the processing and detecting apparatus 100a may not include a detection light source (that is, it may not include the light source module 155). For example, when the processing laser L1 processes the surface S1, the sample 120 to be processed may reflect or scatter the processing laser L1 into detection information L3. Moreover, the detection information L3 may include more than one kind of information. At this time, the dichroic mirror 131 can be replaced by an element capable of selecting specific information, such as a beam splitter or the like, so that the detection information L3 can be passed to the information capturing unit 151, and then scanned to the receiving unit 161 by the scanning output unit 156. In this way, the processing and detecting apparatus 100a can detect the current state of the sample 120 to be processed during processing.

In other words, the detection information L3 that the receiving unit 161 can receive can have many different examples. In addition to adding a different detection light source to generate detection information L3 as above, it is also possible that the processing laser L1 itself has corresponding characteristics, or the processing laser L1 is applied to the sample 120 to be processed and is reflected and scattered, so as to form detection information. L3 which was captured by receiving unit 161. These detection information L3 can be configured to determine a plurality of properties, including but being not limited to the wavelength, spectrum, luminance, etc., of the sample 120 to be processed (such as a micro-light-emitting diode chip). Besides, the light source of the detection information L3 may be realized by one detection light source or a plurality of different detection light sources. Alternatively, if the detection information L3 can be detected without being illuminated by visible light, the detection information L3 can be captured by capturing specific information reflected or scattered back by the sample 120 to be processed when the sample 120 is processed, and an additional detection light source may not be needed.

Therefore, in an embodiment, the receiving unit 161 can be a spectrometer, each piece of detection information includes a spectrum signal of one of the processing positions, and the receiving unit 161 receives a plurality of pieces of detection information to generate an image data.

Or, in an embodiment, the receiving unit 161 is a luminance meter, and each piece of detection information includes the luminance signal of one of the processing positions.

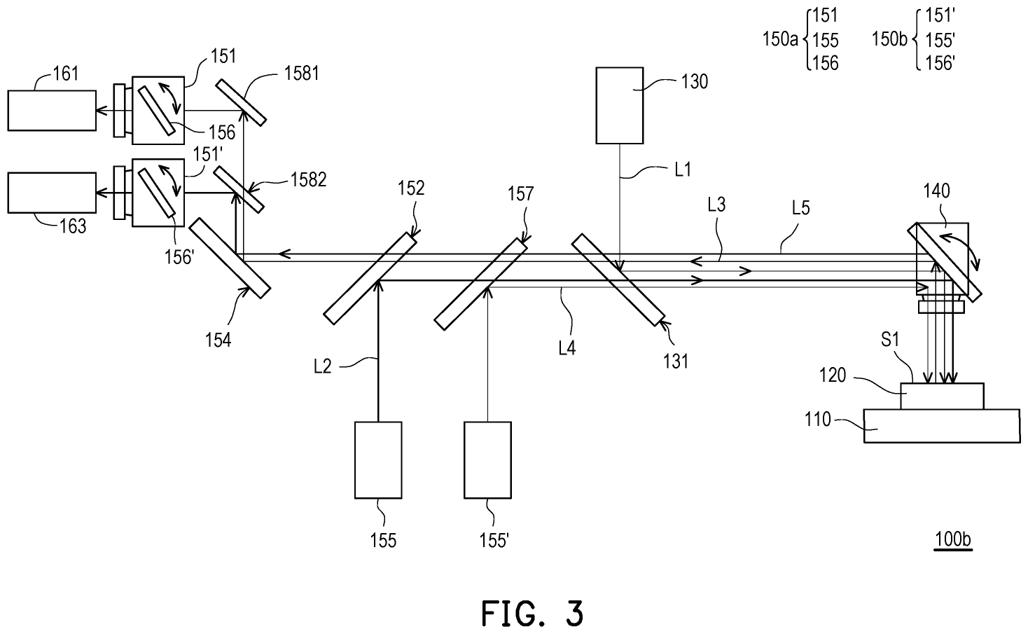

FIG. 3 is a schematic diagram of the light path of a processing and detecting apparatus according to another embodiment of the invention. Please refer to FIG. 3. The difference between FIG. 3 and FIG. 1 is that the processing and detecting apparatus 100b has a plurality of detection scanners, such as a detection scanner 150a and a detection scanner 150b, and the detection information received by each information capturing unit is different. For example, the information capturing unit 151 of the detection scanner 150a and the information capturing unit 151′ of the detection scanner 150b receive different detection information.

The signal source positions received by the scanning output unit 156 and the scanning output unit 156′ are determined by the processing scanner 140, and the light source module 155′ added to the detection scanner 150b is also coaxial, which is achieved by the processing scanner 140.

Specifically, the detection scanner 150a may include a light source module 155, an information capturing unit 151 and a scanning output unit 156, and the detection scanner 150b may include a light source module 155′, an information capturing unit 151′ and a scanning output unit 156′. The detection light L4 emitted by the light source module 155′ is reflected by the beam splitter 157 to the processing scanner 140. After being scanned by the processing scanner 140 on the sample 120 to be processed, the detection light L4 is reflected by the sample 120 to be processed into detection information L5. After detection information L5 and detection information L3 are reflected by reflector 154 via beam splitters 157 and 152, the dichroic mirror 1582 can separate the detection information L3 and the detection information L5. This is because the wavelength of the detection light L2 is different from the wavelength of the detection light L4, so the wavelength of the detection information L3 is also different from the wavelength of the detection information L5, so the two can be separated through the dichroic mirror 1582.

After that, the detection information L3 is reflected to the information capturing unit 151 by the reflector 1581, and the detection information L5 is passed to the information capturing unit 151′. The scanning output unit 156 scans the detection information L3 to the receiving unit 161, and the scanning output unit 156′ scans the detection information L5 to the receiving unit 163.

Therefore, there can be a plurality of sets of detection scanners in this embodiment, and the required light source module or corresponding receiving unit can be added according to the detection sample. In this way, a plurality of detections can be completed at the same time during the laser processing process.

In another embodiment, if the light source module 155 is a multi-wavelength light source, the light source module 155′ may not be used, but only one light source module 155 may be used to provide the detection light L2 and the detection light L4 with two or more wavelengths. In this way, the detection information L3 and the detection information L5 can still be generated correspondingly.

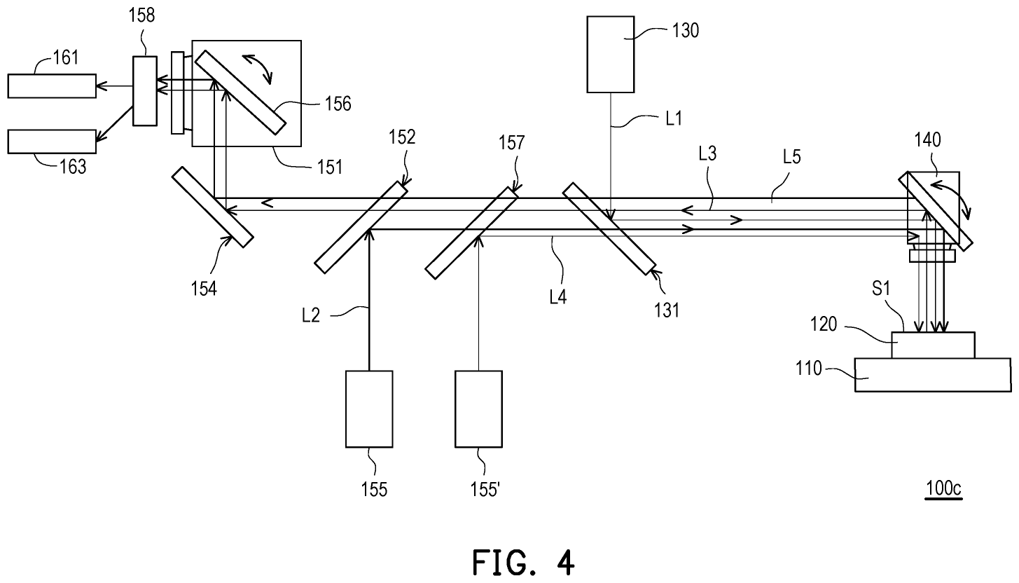

FIG. 4 is a schematic diagram of the light path of a processing and detecting apparatus according to another embodiment of the invention. Please refer to FIG. 4. The difference between FIG. 4 and FIG. 3 is that the processing and the detecting apparatus 100c of this embodiment adopts the combination of an optical modulator 158, an information capturing unit 151 and a scanning output unit 156 to process and separate a plurality of pieces of detection information (such as detection information L3 and detection information L5). In this embodiment, the optical modulator 158 is, for example, an acousto-optic modulator (AOM). When there are a plurality of detection scanners and receiving units, the optical modulator 158 receives a plurality of pieces of detection information (such as detection information L3 and detection information L5) and distributes them to a plurality of receiving units (such as the receiving units 161 and 163). Specifically, the acousto-optic modulator can use the internal acoustic wave field to modulate the frequency or refractive index of different detection information L3 and L5, and thereby interpret and separate the detection information L3 and L5 to determine them to be transmitted to receiving units 161 and 163.

On the other hand, the optical modulator 158 (i.e., acousto-optic modulator) of this embodiment can also be applied to the embodiment of FIG. 1 and is disposed between the scanning output unit 156 and the receiving unit 161. In the embodiment of FIG. 1, the detection light source can be provided by the light source module 155 in the detection scanner 150a. The detection light source can also be continuous light. When in situ and target tracking, the detection light source will move with the movement of the light spot, but during this period, the receiving unit 161 still maintains the exposure state. In an embodiment, an ultra-high-speed complementary metal-oxide-semiconductor (CMOS) device can be used as the receiving unit 161 to be exposed with the pulses of the (pulsed) laser light source of the processing unit 130 at the same frequency. Since the sensing speed of the ultra-high-speed complementary metal oxide semiconductor device is fast enough, an interference problem between a plurality of images IM during the above-mentioned continuous exposure can be effectively reduced.

In another embodiment, instead of using an ultra-high-speed complementary metal oxide semiconductor device as the receiving unit 161, an optical modulator 158 (such as an acousto-optic modulator) can be used to capture the changes in reflected light (such as a wavefront), thereby screening for light with specific conditions to pass through. That is, the optical modulator 158 shields at least part of the detection information L3 and transmits it to the receiving unit 161. In other words, the optical modulator 158 can filter out unwanted noise and is not affected by continuous exposure. Specifically, the optical modulator 158 can first filter out the special frequency of the light spot drag, or use the characteristics of the optical modulator 158 to adjust the light direction at high speed, and only transmit the effective detection information L3 to the receiving unit 161 at a specific moment. For example, the effective detection information L3 is correspondingly transmitted to the corresponding pixel PX. The embodiment using the optical modulator 158 can make the detection signal L3 have stronger brightness, and can simultaneously cope with the requirement of the detection information L3 having a plurality of kinds.

To sum up, in the processing and detecting apparatus according to the embodiment of the invention, the surface of the sample to be processed has a plurality of processing positions, and the processing scanner controls the processing unit with a scanning frequency to process the plurality of processing positions sequentially, the information capturing unit synchronously receives a piece of detection information for each of the plurality of processing positions via the processing scanner, and the scanning output unit is connected to the information capturing unit and outputs each piece of detection information at a scanning frequency. Therefore, when processing the sample to be processed, detection can be performed simultaneously. For example, in the process of mass transfer, massive detection can be carried out simultaneously, replacing the existing multiple station process and improving production efficiency.

What is claimed is:

1. A processing and detecting apparatus, comprising:
a stage configured to place a sample to be processed, wherein a surface of the sample to be processed has a plurality of processing positions;
a processing unit disposed relative to the stage to process the sample to be processed;
a processing scanner, configured to scan the sample to be processed, the processing scanner controls the processing unit to process the processing positions sequentially at a scanning frequency; and
at least one detection scanner, comprising:
an information capturing unit synchronously receiving a piece of detection information for each of the processing positions via the processing scanner; and
a scanning output unit, signally connected to the information capturing unit, and outputting each piece of detection information at the scanning frequency.

2. The processing and detecting apparatus according to claim 1, wherein the at least one detection scanner also comprises a light source module connected to the processing scanner and the information capturing unit, the light source module has a light path, and the light path is controlled by the processing scanner so that the light path is coaxial with a vector of the processing unit relative to each of the processing positions, wherein each piece of detection information is a light signal reflected from the surface of the sample to be processed.

3. The processing and detecting apparatus according to claim 2, wherein the light source module is a continuous light source or a pulse light source.

4. The processing and detecting apparatus according to claim 2, wherein the light source module emits detection light of a single wavelength.

5. The processing and detecting apparatus according to claim 2, wherein the light source module emits multi-wavelength detection light.

6. The processing and detecting apparatus according to claim 1, wherein there are a plurality of detection scanners, and each information capturing unit receives different detection information.

7. The processing and detecting apparatus according to claim 1, wherein the processing unit is a laser light source, and each piece of detection information is the laser light source reflected from the surface of the sample to be processed.

8. The processing and detecting apparatus according to claim 1 further comprising at least one receiving unit connected to the scanning output unit of the detection scanner to receive each piece of detection information.

9. The processing and detecting apparatus according to claim 8, wherein the receiving unit is an image sensor and has a plurality of imaging areas, each piece of detection information includes an image of one of the processing positions, and each piece of detection information is respectively imaged on different imaging areas through the scanning output unit.

10. The processing and detecting apparatus according to claim 8, wherein the receiving unit is a spectrometer, each piece of detection information includes a spectrum signal of one of the processing positions, and the receiving unit receives the pieces of detection information to generate an image data.

11. The processing and detecting apparatus according to claim 8, wherein the receiving unit is a luminance meter, and each piece of detection information includes a luminance signal of one of the processing positions.

12. The processing and detecting apparatus according to claim 8 further includes an optical modulator disposed between the detection scanner and the receiving unit, and the optical modulator shields at least part of the detection information and transmits it to the receiving unit.

13. The processing and detecting apparatus according to claim 12, wherein there are a plurality of detection scanners and a plurality of receiving units, and the optical modulator receives a plurality of pieces of detection information and distributes them to the plurality of receiving units.

14. The processing and detecting apparatus according to claim 1, wherein the scanning output unit is a scanning galvanometer.

15. The processing and detecting apparatus according to claim 1, wherein the information capturing unit includes a lens or a light incident surface.
